(19) United States
(12) Patent Application Publication
(10) Pub. No.: US 2024/0105692 A1
(43) Pub. Date: Mar. 28, 2024

(54) PACKAGED FLIP CHIP RADIO FREQUENCY TRANSISTOR AMPLIFIER CIRCUITS

(71) Applicant: Wolfspeed, Inc., Durham, NC (US)

(72) Inventors: Woo Eng Wah, Ipoh (MY); Liew Soon Lee, Ipoh (MY); Alexander Komposch, Morgan Hill, CA (US); Arthur Fong-Yuen Pun, Raleigh, NC (US); Jeremy Fisher, Raleigh, NC (US)

(21) Appl. No.: 17/951,366

(22) Filed: Sep. 23, 2022

(51) Int. Cl. H01L 25/16; H01L 23/367

(52) U.S. Cl. CPC H01L 25/16; H01L 23/367; H01L 24/06; H01L 2924/13064

(57) ABSTRACT

RF transistor amplifier circuits are provided that comprise a circuit board and an RF transistor amplifier die. The RF transistor amplifier die is flip-chip mounted on an upper surface of the circuit board so that a gate terminal, a drain terminal and a source terminal of the die face the upper surface of the circuit board. These RF transistor amplifier circuits further include a heatsink mounted on an upper surface of the RF transistor amplifier die and a plurality of surface mount circuit elements mounted on the upper surface of the circuit board so that a footprint of the heatsink vertically overlaps each of the plurality of surface mount circuit elements.

### FIELD

The present invention relates to radio frequency (“RF”) transistor amplifier circuits and, more particularly, to techniques for packaging such RF transistor amplifier circuits.

### BACKGROUND

Electrical circuits requiring high power handling capability while operating at high frequencies have become more prevalent. In particular, there is now high demand for RF transistor amplifiers that are used to amplify RF signals at frequencies of, for example, 500 MHz to 28 GHz, or to even higher frequencies. These RF transistor amplifiers often need to exhibit high reliability, good linearity and handle high output power levels. RF transistor amplifiers may be implemented using a variety of different types of power transistors including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally-diffused metal-oxide semiconductor) transistors, and the like.

RF transistor amplifiers may be implemented in silicon or wide bandgap semiconductor materials, such as silicon carbide (“SiC”) and Group III nitride materials. Herein, the term “wide bandgap” refers to semiconductor materials having a bandgap of greater than 1.40 eV. As used herein, the term “Group III nitride” refers to those semiconducting compounds formed between nitrogen and the elements in Group III of the periodic table, usually aluminum (Al), gallium (Ga), and/or indium (In). The term also refers to ternary and quaternary compounds, such as AlGaN and AlInGaN. These compounds have empirical formulas in which one mole of nitrogen is combined with a total of one mole of the Group III elements.

Silicon-based RF transistor amplifiers are typically implemented using LDMOS transistors. Silicon LDMOS RF transistor amplifiers can exhibit high levels of linearity and may be relatively inexpensive to fabricate. Wide bandgap RF transistor amplifiers are typically implemented using Group III nitride based semiconductor materials and are usually implemented as HEMT RF transistor amplifiers. These Group III nitride RF transistor amplifiers are primarily used in applications requiring high power and/or high frequency operation where LDMOS RF transistor amplifiers may have inherent performance limitations. Typically, a plurality of RF transistor amplifiers are formed on a growth substrate by epitaxial growth and standard semiconductor processing techniques, and the growth substrate is then “diced” (cut) to provide a plurality of individual die, each of which includes an RF transistor amplifier. Herein, such die are referred to as RF transistor amplifier die.

In order to increase the output power and current handling capabilities, RF transistor amplifiers are typically implemented in a “unit cell” configuration in which a large number of individual “unit cell” transistors are arranged electrically in parallel to effectively form a single transistor that can handle large current levels. These RF transistor amplifiers may be sold as standalone devices or may be incorporated into RF transistor amplifier circuits that may include multiple RF transistor amplifiers and/or associated circuitry. When an RF transistor amplifier circuit includes multiple RF transistor amplifiers, the multiple RF transistor amplifiers may be coupled in series (e.g., a pre-amplification stage and a main amplification stage) and/or in parallel (e.g., a Doherty amplifier implementation). An RF transistor amplifier circuit may be implemented on a single die in the manner described above, or may be implemented as a so-called monolithic microwave integrated circuit (“MMIC”) that may include one or more interconnected RF transistor amplifier dies as well as any associated matching networks, DC block capacitors and/or other circuit elements.

RF transistor amplifier circuits often include matching circuits, such as (1) impedance matching circuits that are designed to improve the impedance match (for RF signals at the fundamental operating frequency of the amplifier) between the RF transistor amplifier and transmission lines connected thereto and (2) harmonic termination circuits that are designed to at least partly terminate harmonics that may be generated during device operation, such as second and third order harmonics or baseband intermodulation products. The RF transistor amplifiers as well as the impedance matching and harmonic termination circuits may be enclosed in a package that protects the dies from physical damage and/or corrosion. Electrical leads may extend from the package to electrically connect the RF transistor amplifier circuit to external circuit elements such as input and output RF transmission lines and bias voltage sources.

Group III nitride-based RF transistor amplifiers are often used in high power applications. Typically, high levels of heat are generated within a Group III nitride-based RF transistor amplifier die during high power operation. If the RF transistor amplifier die becomes too hot, its performance (e.g., output power, efficiency, linearity, gain, etc.) may deteriorate and/or the RF transistor amplifier die may be damaged. As such, Group III nitride-based RF transistor amplifiers are typically mounted in packages that may be optimized for heat removal, such as a ceramic or over-molded package on a metal flange. The RF transistor amplifier die, the elements of any matching networks (e.g., capacitors, inductors, etc.) and the input/output leads may be interconnected with wires, such as gold and/or aluminum wires. Such an assembly process may be slow and sequential (e.g., one package bonded at a time), and assembly costs may be high (e.g., due to cost of gold wires and expensive wire-bond machines.

### SUMMARY

Pursuant to embodiments of the present invention, transistor packages are provided that include a circuit board, a transistor die that has a gate terminal, a drain terminal and a source terminal, the transistor die flip-chip mounted so that the gate terminal and the drain terminal face the upper surface of the circuit board, a heatsink mounted on an upper surface of the transistor die, and a plurality of surface mount circuit elements mounted on the upper surface of the circuit board so that a footprint of the heatsink vertically overlaps at least one of the plurality of surface mount circuit elements.

In some embodiments, a height of the transistor die is at least 300 microns.

In some embodiments, the heatsink includes a first cut-out region, and a first of the plurality of surface mount circuit elements extends into the cut-out region in the heatsink. In some embodiments, the heatsink completely surrounds the cut-out region. In some embodiments, a height of the first surface mount circuit element is greater than or equal to a height of the transistor die.

In some embodiments, all of the plurality of surface mount circuit elements that are mounted on the upper surface of the circuit board are positioned within a footprint of the heatsink.

In some embodiments, the transistor package further comprises a molding material that at least partially fills a space between the circuit board and the heatsink.

In some embodiments, the heatsink is directly connected to the transistor die through a thermally conductive bonding material.

In some embodiments, the heatsink contacts at least one of the plurality of surface mount circuit elements either directly or through a thermally conductive bonding material.

In some embodiments, the transistor die further includes a solderable metal gate pillar extending from the gate terminal and a solderable metal drain pillar extending from the drain terminal.

In some embodiments, the heatsink includes a plate-like portion that extends in parallel to the circuit board.

In some embodiments, the heatsink further includes a plurality of legs that extend downwardly from the plate-like portion, wherein at least some of the legs are soldered to the circuit board. In some embodiments, a lower surface of the plate-like portion includes a recess, and a first of the plurality of surface mount circuit elements extends upwardly from the circuit board into the recess.

In some embodiments, an upper surface of the circuit board includes a recessed region, and a first of the plurality of surface mount circuit elements extends into the recessed region.

In some embodiments, the transistor die is a Group III nitride based transistor die. In some embodiments, the transistor die is a Group III nitride based radio frequency (“RF”) transistor amplifier die. In some embodiments, the Group III nitride based RF transistor amplifier die is configured to operate at frequencies above 1.4 GHz. In some embodiments, the Group III nitride based RF transistor amplifier die is configured to operate at frequencies above 2.5 GHz. In some embodiments, the Group III nitride based RF transistor amplifier die is configured to operate at frequencies between 2.5 and 6.0 GHz. In some embodiments, the Group III nitride based RF transistor amplifier die is configured to operate at output powers of at least 5 Watts.

In some embodiments, the RF transistor amplifier die is a first RF transistor amplifier die, the transistor package further comprising a second RF transistor amplifier die, wherein the heatsink is directly connected to both the first and second RF transistor amplifier dies through respective thermally conductive bonding materials.

In some embodiments, the source terminal faces the upper surface of the circuit board.

In some embodiments, the transistor die includes silicon carbide. In some embodiments, the transistor die includes gallium nitride based materials.

In some embodiments, the transistor package further comprises an integrated passive device that is mounted on the circuit board, wherein the transistor die is flip-chip mounted on the integrated passive device.

Pursuant to further embodiments of the present invention, transistor packages are provided that include a circuit board, a transistor die that has a gate terminal, a drain terminal and a source terminal, the transistor die flip-chip mounted so that the gate terminal and the drain terminal face the upper surface of the circuit board, a heatsink mounted on an upper surface of the transistor die, the heatsink including at least one cut-out region, and a first surface mount circuit element mounted on the upper surface of the circuit board, the first surface mount circuit element extending into the cut-out region in the heatsink.

In some embodiments, the cut-out region is a closed cut-out region.

In some embodiments, the transistor package further comprises a plurality of additional surface mount circuit elements mounted on the upper surface of the circuit board in between the circuit board and the heatsink.

In some embodiments, the transistor package further comprises a molding material that at least partially fills a space between the circuit board and the heatsink.

In some embodiments, the heatsink is directly connected to the transistor die through a thermally conductive bonding material.

In some embodiments, a first height of the first surface mount circuit element is greater than or equal to a second height of the transistor die.

In some embodiments, the heatsink extends along at least two sides of the cut-out region but does not completely surround the cut-out region.

In some embodiments, the heatsink includes a plate-like portion, and a plurality of legs that extend downwardly from the plate-like portion, wherein at least some of the legs are soldered to the circuit board.

In some embodiments, the transistor die is a Group III nitride based RF transistor amplifier die. In some embodiments, the Group III nitride based RF transistor amplifier die is configured to operate at frequencies between 2.5 and 6.0 GHz. In some embodiments, the Group III nitride based RF transistor amplifier die is configured to operate at output powers of at least 5 Watts.

In some embodiments, the source terminal faces the upper surface of the circuit board.

In some embodiments, the transistor die includes silicon carbide and/or gallium nitride based materials.

Pursuant to still further embodiments of the present invention, transistor packages are provided that include a circuit board, a transistor die mounted directly or indirectly on an upper surface of the circuit board, a heatsink mounted on the transistor die opposite the circuit board, the heatsink including a plate-like portion that extends parallel to the circuit board, where a lower surface of the plate-like portion includes a recess, and a surface mount circuit element mounted on an upper surface of the circuit board and extending into the recess.

In some embodiments, a maximum depth of the recess is at least one third a thickness of the plate-like portion of the heatsink.

In some embodiments, the transistor package further comprises a molding material that at least partially fills a space between the circuit board and the heatsink.

In some embodiments, the heatsink is directly connected to the transistor die through a thermally conductive bonding material.

In some embodiments, the transistor package further comprises a plurality of additional surface mount circuit elements mounted on the upper surface of the circuit board, wherein the heatsink contacts at least one of the plurality of additional surface mount circuit elements either directly or through a thermally conductive bonding material.

In some embodiments, the transistor die is an RF transistor amplifier die that includes a gate terminal, a drain terminal and a source terminal, and the RF transistor amplifier die is flip-chip mounted on an upper surface of the circuit board so that at least the gate terminal and the drain terminal face the upper surface of the circuit board. In some embodiments, the transistor die is a Group III nitride based radio frequency transistor amplifier die. In some embodiments, the RF transistor amplifier die is a first RF transistor amplifier die, the transistor package further comprising a second RF transistor amplifier die, wherein the heatsink is directly connected to both the first and second RF transistor amplifier dies through respective thermally conductive bonding materials.

In some embodiments, the heatsink includes a plate-like portion, and a plurality of legs that extend downwardly from the plate-like portion, wherein at least some of the legs are soldered to the circuit board.

Pursuant to additional embodiments of the present invention, transistor packages are provided that include a printed circuit board that includes a recessed region in its upper surface that has a reduced thickness as compared to a second region of the printed circuit board, a transistor die mounted on a first region of the printed circuit board, and a surface mount circuit element mounted on the printed circuit board in the recessed region.

In some embodiments, the transistor package further comprises a heatsink that is mounted on the transistor die opposite the printed circuit board.

In some embodiments, the transistor package further comprises a molding material that at least partially fills a space between the printed circuit board and the heatsink.

In some embodiments, the heatsink is directly connected to the transistor die through a thermally conductive bonding material.

In some embodiments, the heatsink contacts at least one of a plurality of additional surface mount circuit elements either directly or through a thermally conductive bonding material.

In some embodiments, the transistor die is an RF transistor amplifier die includes a gate terminal, a drain terminal and a source terminal, the RF transistor amplifier die flip-chip mounted on an upper surface of the circuit board so that the gate terminal and the drain terminal face the upper surface of the circuit board. In some embodiments, the RF transistor amplifier die is a Group III nitride based RF transistor amplifier die.

In some embodiments, the heatsink includes a plate-like portion, and a plurality of legs that extend downwardly from the plate-like portion, wherein at least some of the legs are soldered to the circuit board.

Pursuant to yet additional embodiments of the present invention, transistor packages are provided that include a circuit board, an integrated passive device mounted on the circuit board, a transistor die that has a gate terminal, a drain terminal and a source terminal, the transistor die flip-chip mounted on an upper surface of the integrated passive device so that the gate terminal and the drain terminal face the upper surface of the integrated passive device, a heatsink mounted on an upper surface of the transistor die, and a plurality of surface mount circuit elements mounted on the upper surface of the circuit board so that a footprint of the heatsink vertically overlaps at least a first of the plurality of surface mount circuit elements.

In some embodiments, a height of the first of the plurality of surface mount circuit elements is greater than a height of the transistor die.

In some embodiments, the transistor package further comprises a molding material that at least partially fills a space between the circuit board and the heatsink.

In some embodiments, the heatsink is directly connected to the transistor die through a thermally conductive bonding material.

In some embodiments, the heatsink contacts at least one of the plurality of surface mount circuit elements either directly or through a thermally conductive bonding material.

In some embodiments, the heatsink includes a plate-like portion that extends in parallel to the circuit board. In some embodiments, the heatsink further includes a plurality of legs that extend downwardly from the plate-like portion, wherein at least some of the legs are soldered to the circuit board. In some embodiments, a lower surface of the plate-like portion includes a recess, and a first of the plurality of surface mount circuit elements extends upwardly from the circuit board into the recess.

In some embodiments, an upper surface of the circuit board includes a recessed region, and a first of the plurality of surface mount circuit elements extends into the recessed region.

### BRIEF DESCRIPTION OF THE DRAWINGS

FIG. 1 is a schematic circuit diagram of a conventional two-stage RF transistor amplifier circuit that includes an input matching circuit.

FIG. 2A is a schematic plan view of an RF transistor amplifier circuit according to embodiments of the present invention.

FIG. 2B is a schematic cross-sectional view of the RF transistor amplifier circuit of FIG. 2A taken along line 2B-2B of FIG. 2A.

FIG. 2C is a schematic perspective view of the RF transistor amplifier circuit of FIGS. 2A-2B.

FIG. 2D is a schematic bottom view of the RF transistor amplifier circuit of FIGS. 2A-2B.

FIG. 2E is a schematic side view of an RF transistor amplifier die illustrating how gate, drain and source interconnects may be connected to the respective gate, drain and source terminals by pillars.

FIG. 3A is a schematic plan view of an RF transistor amplifier circuit according to embodiments of the present invention with a heatsink thereof omitted.

FIG. 3B is a schematic plan view of the RF transistor amplifier circuit of FIG. 3A with the heatsink in place.

FIG. 3C is a schematic cross-sectional view of the RF transistor amplifier circuit of FIG. 3B taken along line 3C-3C of FIG. 3B.

FIG. 4A is a schematic plan view of an RF transistor amplifier circuit according to further embodiments of the present invention with a heatsink thereof omitted.

FIG. 4B is a schematic plan view of the RF transistor amplifier circuit of FIG. 4A with the heatsink in place.

FIG. 4C is a schematic cross-sectional view of the RF transistor amplifier circuit of FIG. 4B taken along line 4C-4C of FIG. 4B.

FIG. 5A is a schematic plan view of an RF transistor amplifier circuit according to additional embodiments of the present invention that includes RF transistor amplifier dies that have increased heights (thicknesses).

FIG. 5B is a schematic cross-sectional view of the RF transistor amplifier circuit of FIG. 5A taken along line 5B-5B of FIG. 5A.

FIG. 6 is a schematic cross-sectional view of a modified version of the RF transistor amplifier circuit of FIGS. 5A-5B.

FIG. 7 is a schematic cross-sectional view of an RF transistor amplifier circuit according to still further embodiments of the present invention that includes a heatsink having a recess in its lower surface.

FIGS. 8-12 are schematic cross-sectional views of RF transistor amplifier circuits according to yet additional embodiments of the present invention.

FIG. 13A is a schematic plan view of the RF transistor amplifier die that may be used in the RF transistor amplifier circuits according to embodiments of the present invention.

FIG. 13B is a schematic cross-sectional view of the RF transistor amplifier die of FIG. 13A taken along line 13B-13B of FIG. 13A.

### DETAILED DESCRIPTION

RF transistor amplifier circuits are typically manufactured by a semiconductor manufacturer and then sold to customers who typically mount the RF transistor amplifier circuit on a printed circuit board of a larger electronic system (which is typically referred to as a customer motherboard). Consequently, packaged RF transistor amplifier circuits preferably are designed so that they can be readily mounted on a customer motherboard. Moreover, as discussed above, the RF transistor amplifiers included in packaged RF transistor amplifier circuits often generate large amounts of heat. In order to dissipate this heat, RF transistor amplifier circuits are often mounted on a thermally conductive carrier substrate or submount, such as a metal slug, leadframe, or flange, to vent the heat generated by the RF transistor amplifier die from the amplifier package.

In many cases, an RF transistor amplifier circuit will be implemented as a plurality of discrete components such as one or more RF transistor amplifier die along with additional circuit elements such as surface mount capacitors, inductors and/or resistors. Printed circuit boards provide a simple and convenient way of interconnecting such components, as the components can be soldered to pads on the printed circuit board and RF transmission lines (e.g., microstrip transmission lines) may be formed in the printed circuit that electrically interconnect the components in a desired fashion. In some cases, the components can be interconnected solely through such RF transmission lines, eliminating the need for bond wire connections between components. This can be advantageous as bond wires can be potential mechanical failure points, are labor intensive to form, may add excess inductance that can negatively impact performance in some applications, and can be potential source of passive intermodulation distortion.

Printed circuit boards, however, do not provide a good thermal dissipation path to dissipate heat generated in the RF transistor amplifier die. As a result, packaged RF transistor amplifier circuits often mount the RF transistor amplifier die (and often at least some of the other circuit components) on a central region of a metal flange or other heatsink, and a printed circuit board with a large opening in the middle is also mounted on the heatsink to surround the RF transistor amplifier die and other circuit components that are mounted directly on the heatsink. RF transmission lines on the printed circuit board may serve as input and output leads of the package, and in some cases additional circuit components may be mounted on the printed circuit board and interconnected by RF transmission lines formed in the printed circuit board. In such an implementation, the gate and drain terminals of the transistor amplifier are formed on the upper side of the RF transistor amplifier die(s) and the source terminal of the transistor amplifier is formed on the lower side of each RF transistor amplifier die. The metal flange or other heatsink may be used to vent heat generated in the RF transistor amplifier die from the package, and may also provide the electrical connections to the source terminals of the RF transistor amplifier dies.

Semiconductor devices such as RF transistor amplifier dies may be mounted in a so-called “flip-chip” configuration where the semiconductor die is flipped over so that the “front” side of the semiconductor die (i.e., the side of the die in which the active region that includes the unit cell transistors is formed) is attached to the mounting substrate, and the opposed “back” side of the die is left exposed. If an RF transistor amplifier die is mounted in flip-chip configuration on a printed circuit board, then a heatsink may be attached to the exposed back side of the semiconductor die. As most Group III nitride based RF transistor amplifier die are formed on silicon carbide substrates—which have high thermal conductivity—such a heatsink configuration may be very effective at dissipating heat from the RF transistor amplifier die. However, the RF transistor amplifier die are typically relatively thin (e.g., have a thickness or “height” of less than 100 microns), and hence may be thinner than other of the circuit elements. The heatsink is typically designed to have a large area in the length and width directions (which are perpendicular to the thickness direction), and either directly contacts the RF transistor amplifier die or is attached to the RF transistor amplifier die through a thermally conductive solder, as such an arrangement facilitates good heat dissipation. Unfortunately, however, this also means that circuit elements that are thicker than the RF transistor amplifier die must be spaced outside the “footprint” of the heatsink. Herein, the “footprint” of a heatsink of an RF transistor amplifier circuit refers to the projection of an outer perimeter of the heatsink onto an underlying circuit board of the RF transistor amplifier circuit when the heatsink is viewed along an axis that extends perpendicular to the major surfaces of the circuit board. This increases the overall size (and cost) of the packaged RF transistor amplifier die, and may also reduce the performance thereof as the longer RF transmission lines result in increased insertion losses. While these disadvantages may be avoided by reducing the size of the heatsink, a smaller heatsink will be less effective at dissipating the heat generated in the RF transistor amplifier die.

Pursuant to embodiments of the present invention, packaged RF transistor amplifier circuits are provided having one or more RF transistor amplifier die that are flip-chip mounted on a printed circuit board. The RF transistor amplifier die may have gate, drain and source terminals on a front side thereof (i.e., the side of the die that includes the active region), allowing the RF transistor die to be electrically connected to the printed circuit board through direct soldered connections, reducing or eliminating the need for bond wire connections. A heatsink may be mounted to directly contact the opposed back side of each RF transistor amplifier die, facilitating removing heat from these die. Moreover, the RF transistor amplifier die, the heatsink and/or the printed circuit board may be modified to accommodate mounting surface mount circuit elements on the printed circuit board within the footprint of the heatsink, even though at least some of these surface mount circuit elements may be taller than the RF transistor amplifier die. These techniques allow the use of a large heatsink while facilitating mounting most or all of the surface mount circuit elements of the RF transistor amplifier circuit on the printed circuit board within the footprint of the heatsink.

In some embodiments, the heatsink may include one or more cut-out regions that are positioned to vertically overlap locations where relatively tall surface mount circuit elements are mounted on the printed circuit board. Herein, a first element “vertically overlaps” a second element that is mounted on a printed circuit board if an axis that is perpendicular to the major surfaces of the printed circuit board intersects both the first element and the second element. By having the cut-out regions vertically overlap the taller surface mount circuit elements, these surface mount circuit elements may extend though the openings created by the cut-out regions, allowing the heatsink to be mounted directly on the RF transistor amplifier die(s) even though surface mount circuit elements that are taller than the RF transistor amplifier die(s) are within the footprint of the heatsink. In some embodiments, the cut-out regions may be “closed” cut-out regions where the heatsink surrounds the cut-out region on all sides when viewed from above. In other embodiments, the cut-out regions may be “open” cut-out regions where the heatsink extends along at least two sides of the cut-out region but does not completely surround the cut-out region.

In other embodiments, the thickness or “height” of the RF transistor amplifier die may be increased so that RF transistor amplifier die may be at least as tall as at least some of the surface mount circuit elements. By increasing the thickness of the RF transistor amplifier die, it becomes possible to mount the surface mount circuit elements on the printed circuit board within the footprint of the heatsink while having the heatsink directly contact the RF transistor amplifier die. Typically, gallium nitride based RF transistor amplifier die are manufactured to have a thickness on the order of 75-100 microns, as such a thickness may help ensure that conductive vias that extend through the RF transistor amplifier die (e.g., vias that connect the source metallization on the upper surface of the die to a ground plane on the lower surface of the die) do not become too wide, which may require increasing the pitch of the unit cell transistors included in the RF transistor amplifier die. Pursuant to embodiments of the present invention, the connection between the source metallization of the die and an external source connection may be provided on the front side of the die, eliminating the need for source vias. When the RF transistor amplifier die no longer include source vias, they can be made significantly thicker (e.g., 350 microns or more) without any significant corresponding changes in either electrical or heat dissipation performance. Moreover, gallium nitride based RF transistor amplifier die are normally formed on thick growth substrates, and then a portion of the growth substrate is removed through a grinding process to shorten the die to a desired height. Thus, thicker RF transistor amplifier die can be provided simply by performing less grinding, meaning that thicker RF transistor amplifier dies may be provided without any new processing steps are required and an existing processing step can be shortened.

In still other embodiments, recesses may be formed in either the printed circuit board or the heatsink that provide additional “head room” to accommodate surface mount circuit elements that are taller than the RF transistor amplifier die. For example, one or more regions in the lower surface of the heatsink may be chemically etched to selectively reduce the thickness of the heatsink in locations that vertically overlap taller surface mount circuit elements. As another example, recessed regions may selectively be formed in the upper surface of the printed circuit board in locations where the taller surface mount circuit elements are to be mounted. These recesses may provide the additional head room necessary to mount these taller surface mount elements within the footprint of the heatsink.

It will also be appreciated that while the techniques disclosed herein may be particularly useful with respect to RF transistor amplifier circuits that are mounted on a printed circuit board and include a heatsink, embodiments of the present invention are not limited thereto. For example, the techniques disclosed herein may be used in packaging any transistor, including, for example, silicon carbide based power transistors. Thus, while the various embodiments depicted in the attached figures each include one or more RF transistor amplifier die, it will be appreciated that in other embodiments these RF transistor amplifier die may comprise other types of transistors such as, for example, power transistors.

Thus, pursuant to some embodiments, transistor packages are provided that comprise a circuit board and a transistor die that has a gate terminal, a drain terminal and a source terminal. The transistor die is flip-chip mounted on an upper surface of the circuit board so that at least the gate terminal and the drain terminal face the upper surface of the circuit board. These transistor packages further include a heatsink mounted on an upper surface of the transistor die and a plurality of surface mount circuit elements mounted on the upper surface of the circuit board so that a footprint of the heatsink vertically overlaps at least one surface mount circuit element.

In some embodiments, the heatsink is directly connected to the transistor die through a thermally conductive bonding material. In some embodiments, a height of the transistor die is at least 300 microns. In other embodiments, the heatsink includes a first cut-out region, and a first of the plurality of surface mount circuit elements extends into the cut-out region in the heatsink. In still other embodiments, the heatsink includes a plate-like portion that extends in parallel to the circuit board, a lower surface of the plate-like portion includes a recess, and a first of the plurality of surface mount circuit elements extends upwardly from the circuit board into the recess. In still further embodiments, an upper surface of the circuit board includes a recessed region, and a first of the plurality of surface mount circuit elements extends into the recessed region.

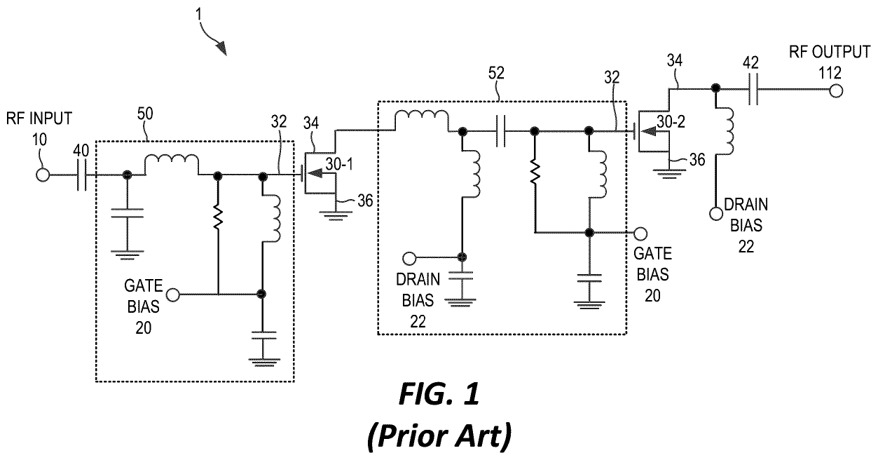

Before discussing the RF transistor amplifier circuits according to embodiments of the present invention, it is helpful to discuss the circuit design of an example RF transistor amplifier circuit. FIG. 1 is a schematic circuit diagram of a two-stage RF transistor amplifier circuit design.

As shown in FIG. 1, the RF transistor amplifier circuit 1 includes an RF input lead 10, a first stage RF transistor amplifier 30-1, a second stage RF transistor amplifier 30-2 and an RF output lead 12. Each RF transistor amplifier 30 is implemented as a Group III nitride based HEMT that has a gate terminal 32, a drain terminal 34 and a source terminal 36. Each RF transistor amplifier 30 may have a unit cell structure in which a large number of unit cell HEMT transistors are connected in parallel to the gate, drain and source terminals 32, 34, 36.

Respective gate bias voltage inputs 20 are coupled to the gate terminals 32 of each RF transistor amplifier 30, and respective drain bias voltage inputs 22 are coupled to the drain terminals 34 of each RF transistor amplifier 30. The source terminal 36 of each RF transistor amplifier 30 is coupled to ground. An input DC blocking capacitor 40 and an input matching network 50 are coupled between the RF input lead 10, and the first stage RF transistor amplifier 30-1. An output DC blocking capacitor 42 is coupled between the second stage RF transistor amplifier 30-2 and the RF output lead 12. An interstage impedance matching network 52 is coupled between the drain terminal 34 of the first stage RF transistor amplifier 30-1 and the gate terminal 32 of the second stage RF transistor amplifier 30-2. While RF transistor amplifier circuit 1 is not shown as including an output matching circuit, it will be appreciated that an output impedance matching circuit and/or an output harmonic termination circuit may be coupled between the drain terminal 34 of the second stage RF transistor amplifier 30-2 and the RF output lead 12.

Example embodiments of the present invention will now be discussed in further detail with reference to the figures.

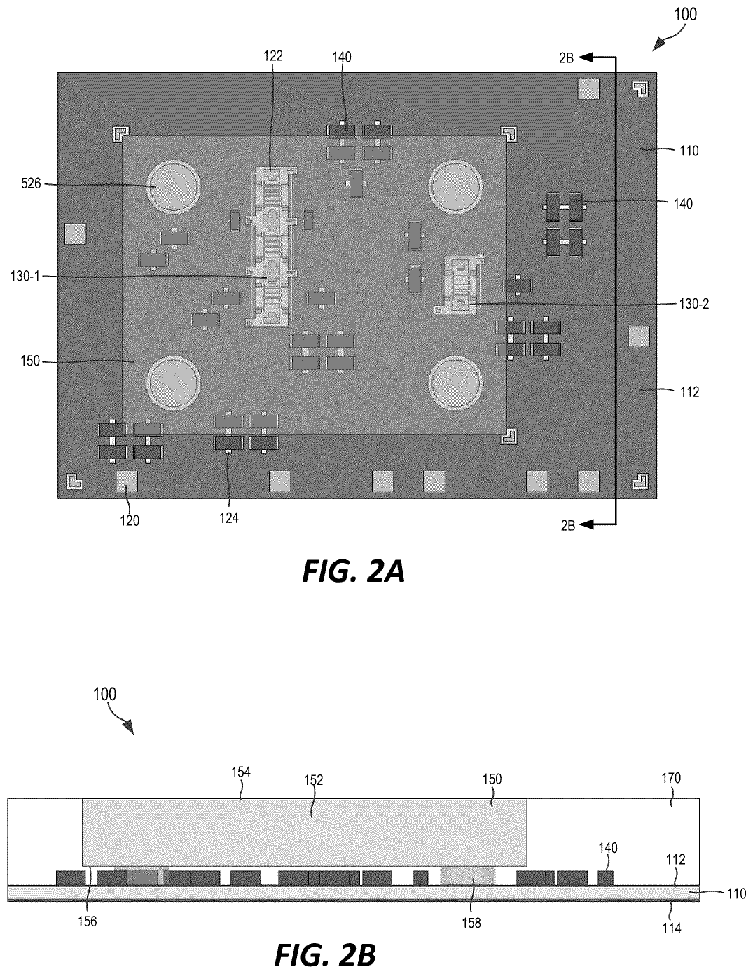

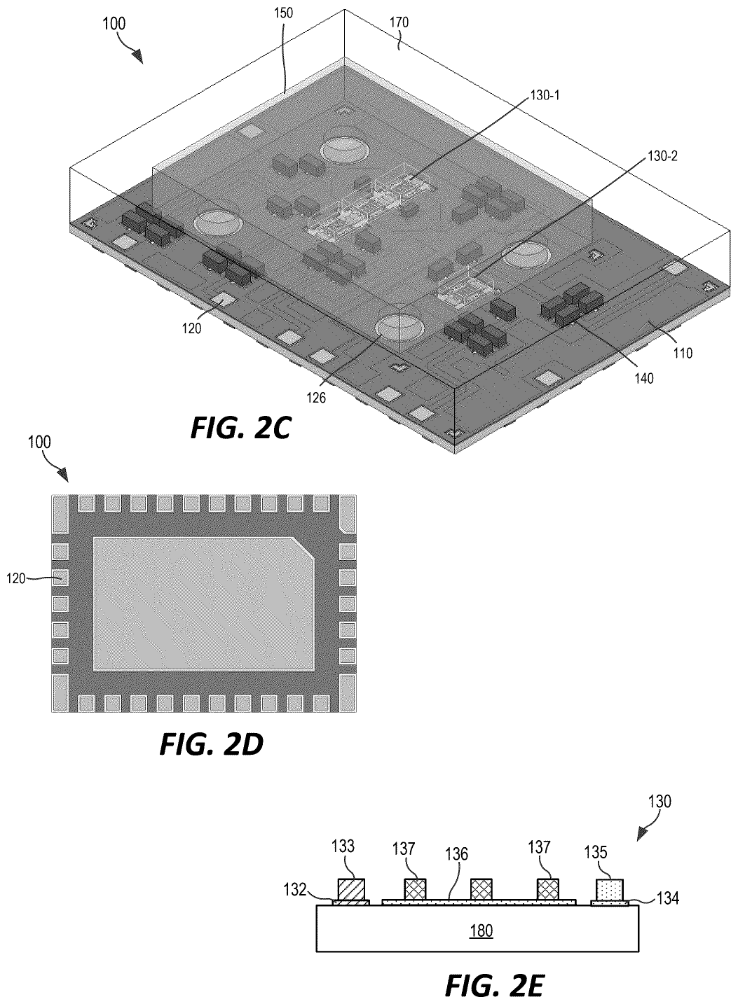

FIG. 2A is a schematic plan view of an RF transistor amplifier circuit 100 according to embodiments of the present invention. FIG. 2B is a schematic cross-sectional view of the RF transistor amplifier circuit 100 of FIG. 2A taken along line 2B-2B of FIG. 2A. FIG. 2C is a schematic perspective view of the RF transistor amplifier circuit 100 of FIGS. 2A-2B. FIG. 2D is a schematic bottom view of the RF transistor amplifier circuit 100 of FIGS. 2A-2B

As shown in FIGS. 2A-2D, the RF transistor amplifier circuit 100 includes a printed circuit board 110, first and second RF transistor amplifier dies 130-1, 130-2, a plurality of surface mount circuit elements 140, a heat sink 150 and an overmold encapsulation 170.

The printed circuit board 110 may comprise an RF-grade printed circuit board that has an upper surface 112 and a lower surface 114. A plurality of metal pads 120, 122, 124, 126 are provided on the upper surface of the printed circuit board 110. Pads 120 may comprise input/output pads that receive electrical input signals from external circuits or that deliver electrical output signals to external circuits. The input and output signals may comprise, for example, RF signals and DC bias voltage signals. The external circuits may be, for example, circuit elements that are mounted on a customer motherboard. Pads 122 (which are barely visible in the figures) may comprise mounting pads for the first and second RF transistor amplifier dies 130-1, 130-2 and may include at least three pads 122 per RF transistor amplifier die 130, namely a gate pad, a drain pad and a source pad. Electrical connections between the first and second RF transistor amplifier dies 130-1, 130-2 and the printed circuit board 110 may be made through the pads 122. Pads 124 (which are barely visible in the figures) may comprise mounting pads for the surface mount circuit elements 140. Electrical connections between the surface mount circuit elements 140 and the printed circuit board 110 may be made through the pads 124. Pads 126 may comprise mounting pads for posts of the heatsink 150 (see discussion below).

The RF transistor amplifier die 130 and the surface mount circuit elements 140 may be mounted on the pads 122, 124 on the printed circuit board 110 using, for example, solder bumps, conductive epoxy, die attach materials (such as eutectic materials), precoats (e.g., a gold-tin precoat), solder pre-forms, sintering (e.g., Ag-sintering) and the like, which are collectively referred to herein as thermally conductive bonding materials.

As shown in FIG. 2D, a metal pad 128 is formed over most of the lower surface 114 of printed circuit board 110. The metal pad 128 may be electrically floating or electrically grounded. The metal pad 128 facilitates attaching the heatsink 150 to the RF transistor amplifier die 130. Additional input/output pads 120 are also provided around the periphery of the ground plane 128. While not shown in FIGS. 2A-2D, RF transmission lines such as microstrip transmission lines may be formed in the printed circuit board 110.

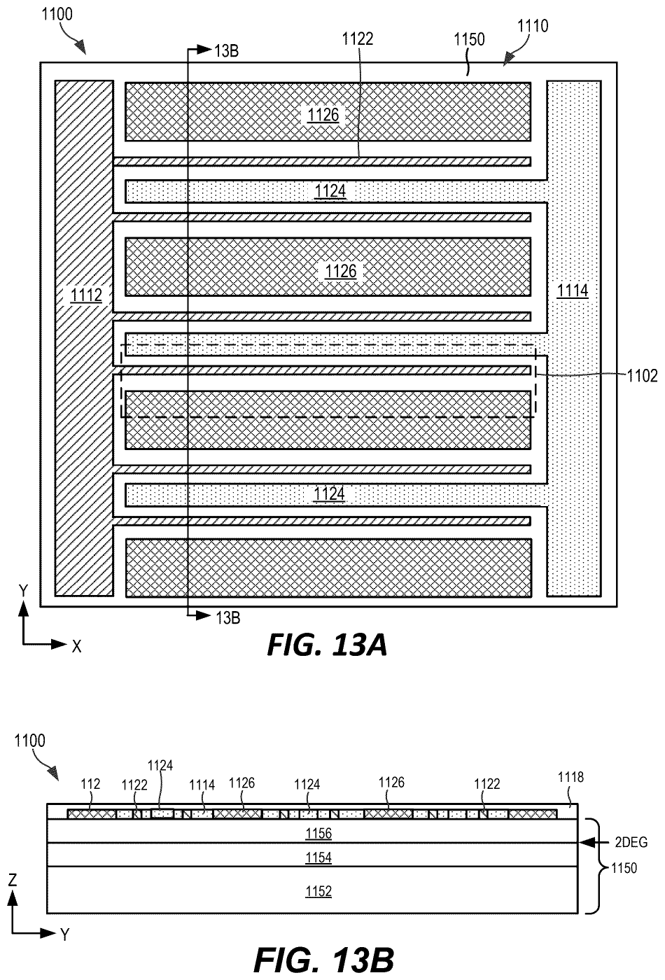

The RF transistor amplifier dies 130-1, 130-2 may each be Group III nitride based RF transistor amplifier dies. Further details regarding an example implementation of RF transistor amplifier dies 130-1, 130-2 is provided below with reference to FIGS. 13A-13B. Each RF transistor amplifier die 130 includes a gate terminal 132, a drain terminal 134 and a source terminal 136. In addition, as discussed above with reference to FIG. 2E, each RF transistor amplifier die 130 may further include a solderable gate interconnect 133 that extends from and is electrically connected to the gate terminal 132, a solderable drain interconnect 135 that extends from and is electrically connected to the drain terminal 134, and a solderable source interconnect 137 that extends from and is electrically connected to the source terminal 136. Each RF transistor amplifier die 130 is flip-chip mounted on the printed circuit board 110 so that the front side of each RF transistor amplifier die 130 faces the printed circuit board 110. The front side of each RF transistor amplifier die 130 is the surface where the active region of the HEMT is formed, and the gate, drain and source terminals 132, 134, 136 are on this front side. While FIG. 2E shows all three of the gate, drain and source terminals 132, 134, 136 as being located on the front side of the die, it will be appreciated that embodiments of the present invention are not limited thereto. For example, in other embodiments, the source terminal 136 may instead be located on the back side of the die and may be connected to source fingers of the device through conductive vias that extend through the die.

FIG. 2E is a cross-sectional view of RF transistor amplifier die 130 that is taken along one of the gate fingers thereof. In FIG. 2E, the semiconductor layer structure and lower metallization levels of the die are generically shown by the block labeled 180. As shown in FIG. 2E, each RF transistor amplifier die 130 may include interconnect structures that facilitates flip-chip mounting the RF transistor amplifier dies 130 on the printed circuit board 110. As shown in FIG. 2E, the gate terminal 132, drain terminal 134 and source terminal 136 may be formed on the front side of the semiconductor layer structure of RF transistor amplifier die 130. A solderable gate interconnect 133 in the form of a plurality of metal gate pillars 133 are mounted on the gate terminal 132, a solderable drain interconnect 135 in the form of a plurality of metal drain pillars 135 are mounted on the drain terminal 134, and a solderable source interconnect 137 in the form of a plurality of metal source pillars 137 are mounted on the source terminal 136. In the cross-sectional view of FIG. 2E only one metal gate pillar 133 and one metal drain pillar 135 are visible, but it will be appreciated that a plurality of these pillars may be provided. It will also be appreciated that the solderable gate, drain and source interconnects 133, 135, 137 may take other forms than metal pillars, such as, for example, a patterned metal layer that is formed on the gate, drain and source terminals. The solderable gate interconnect 133 may be soldered to a gate pad 122 on printed circuit board 110, the solderable drain interconnect 135 may be soldered to a drain pad 122 on printed circuit board 110, and the solderable source interconnect 137 may be soldered to a source pad 122 on printed circuit board 110. In this fashion, each RF transistor amplifier die 130 may be physically mounted on the printed circuit board 110 and may be electrically connected to respective gate, drain and source pads on the printed circuit board 110.

The surface mount circuit elements 140 may comprise, for example, individually packaged capacitors, inductors, resistors and the like. Each surface mount circuit element 140 may include pads or other metal contacts 142 (barely visible in the figures) that are used to solder the surface mount circuit elements 140 to the pads 124 on printed circuit board 110. The pads 124 and contacts 142 are used to pass electrical signals (e.g., RF signals) between RF transmission lines on the printed circuit board 110 and the surface mount circuit elements 140. The surface mount circuit elements 140 may, for example, be used to form matching circuits for the RF transistor amplifier circuit 100 such as the input matching circuit 50 and the interstage matching circuit 52 that are illustrated in FIG. 1, or other circuit elements of the RF transistor amplifier circuit 100 such as the blocking capacitors 40, 42.

The heatsink 150 is used to dissipate heat from the RF transistor amplifier dies 130-1, 130-2. The heatsink 150 may comprise a metal plate-like region 152 that has an upper surface 154 and a lower surface 156. A stamping operation may be performed where the metal plate-like region 152 is placed on a die surface that includes recesses. A stamping tool is used to impact the upper surface 154 of the metal plate-like region 152 to form a plurality of legs 158 that extend downwardly from the lower surface 156 of the metal plate-like region 152 to form the heatsink 150. The legs 158 may have a height (as measured downwardly from the lower surface 156 of the plate-like region 152) that is the same as or slightly larger than a height of the RF transistor amplifier die 130-1, 130-2.

As described above, the RF transistor amplifier dies 130-1, 130-2 are flip-chip mounted on the printed circuit board 110. The lower surface 156 of the plate-like region 152 of the heatsink 150 may be mounted on the back side of each RF transistor amplifier die 130-1, 130-2. In some embodiments, the heatsink 150 may be soldered to the lower surface of each RF transistor amplifier die 130-1, 130-2 using, for example, a conductive bonding material. The heatsink 150 may draw Heat that is generated in the active region of each RF transistor amplifier die 130-1, 130-2 may pass through the silicon carbide substrate of the die 130 and into the heatsink 150, where it is vented from the packaged RF transistor amplifier circuit 100.

The molding 170 may comprise an underfill material such as capillary underfill material and may be injected to fill in the space between the printed circuit board 110 and the heatsink 150, and to also cover exposed portions of the upper surface 112 of the printed circuit board 110 and side surfaces of the heatsink 150.

The packaged RF transistor amplifier circuit 100 may have a number of advantages. The printed circuit board 110 may, for example, be readily soldered onto a customer motherboard to quickly and easily install the packaged RF transistor amplifier circuit 100 into a larger electronic system. The packaged RF transistor amplifier circuit 100 may interconnect the RF transistor amplifier die 130 and the surface mount circuit elements 140 using RF transmission lines on the printed circuit board 110, which may have low insertion loss and which may not add excessive amounts of inductance as can happen when bond wire connections are used. The packaged RF transistor amplifier circuit 100 may be quickly assembled by simply soldiering the packaged RF transistor amplifier dies 130 and the surface mount circuit elements 140 to the printed circuit board 110, and then soldering the heatsink 150 to the printed circuit board 110 and the packaged RF transistor amplifier dies 130. Finally, the molding 170 may be inserted in the open space in between the printed circuit board 110 and the heatsink 150 and on the side surfaces of the heatsink 150.

As described above, one complication with the RF transistor amplifier circuit 100 is that it may not be suitable for devices that include larger surface mount circuit elements that have a height that exceeds a height of the RF transistor amplifier die 130, as such larger surface mount circuit elements cannot be mounted underneath the heatsink 150 while also allowing the heatsink 150 to be soldered to the RF transistor amplifier dies 130. Pursuant to further embodiments of the present invention, RF transistor amplifier circuits are provided that have features that allow these larger surface mount circuit elements to be mounted within the footprint of the heatsink.

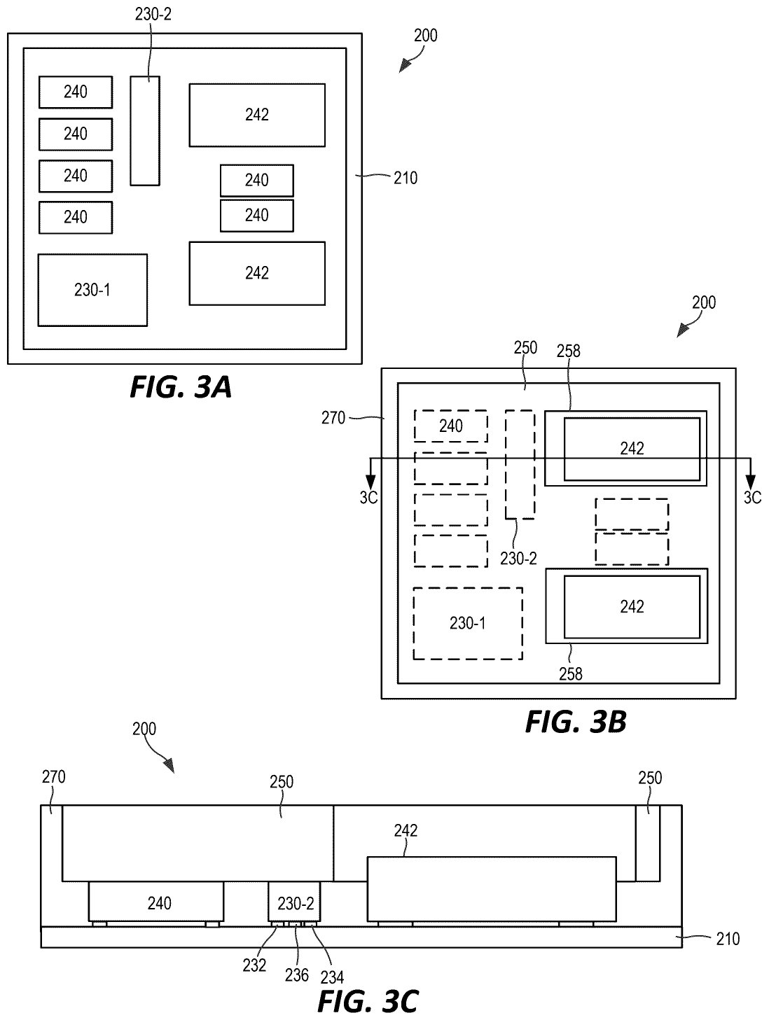

FIGS. 3A-12 illustrate RF transistor amplifier circuits according to embodiments of the present invention that allow larger surface mount circuit elements to be mounted within the footprint of the heatsink. These figures depict simplified RF transistor amplifier circuits for ease of description. The components of these RF transistor amplifier circuits are implemented using the same or similar components as the RF transistor amplifier circuit of FIGS. 2A-2D, and these same or similar components are numbered using similar numbering to the components in FIGS. 2A-2D (specifically, increased by multiples of one hundred). The description of these same or similar components that follow will focus on the differences (if any) between these components and the same/similar components discussed above with reference to FIGS. 2A-2D. It will be appreciated that the base description of these components provided above in the discussion of the RF transistor amplifier circuit 100 of FIGS. 2A-2D applies equally to the same/similar components of the RF transistor amplifier circuits of FIGS. 3A-8, except where noted otherwise.

FIG. 3A is a schematic plan view of an RF transistor amplifier circuit 200 according to embodiments of the present invention. In FIG. 3A, the heatsink and molding of the RF transistor amplifier circuit 200 are omitted to show the underlying elements. FIG. 3B is a schematic plan view of the RF transistor amplifier circuit 200 of FIG. 3A with the heatsink 250 and molding 270 thereof in place. FIG. 3C is a schematic cross-sectional view of the RF transistor amplifier circuit 200 of FIG. 3B taken along line 3C-3C of FIG. 3B.

As shown in FIG. 3A, RF transistor amplifier circuit 200 includes a printed circuit board 210. First and second RF transistor amplifier dies 230-1, 230-2 are flip-chip mounted on printed circuit board 210. A plurality of surface mount circuit elements including small surface mount circuit elements 240 and large surface mount circuit elements 242 are mounted on printed circuit board 210. The printed circuit board 210, the RF transistor amplifier dies 230-1, 230-2 and the surface mount circuit elements 240, 242 may be identical to the corresponding components described above with reference to FIGS. 2A-2D and may be interconnected in the same way as described above.

FIG. 3B is a plan view of RF transistor amplifier circuit 200 after a heatsink 250 thereof has been mounted on the printed circuit board 210 and the RF transistor amplifier die 230 in the manner discussed above with reference to the corresponding elements of RF transistor amplifier circuit 100. The legs of heatsink 250 (corresponding to the legs 158 of heatsink 150) are omitted in FIGS. 3B-3C to simplify the figures. As shown, the heatsink 250 includes a plurality of cut-out regions 258. The cut-out regions 258 comprise regions where the metal has been completely removed (e.g., by stamping). The cut-out regions 258 vertically overlap the large surface mount circuit elements 242. The cut-out regions 258, when viewed from above, are larger than the large surface mount circuit elements 242. This allows the large surface mount circuit elements 242 to extend into the openings in the heatsink 250 provided by the cut-out regions 258, as shown in FIGS. 3B and 3C. The cut-out regions 258 are “closed” cut-out regions meaning that the heatshield 250 fully surrounds the cut-out regions 258 (i.e., extends around all sides of the cut-out regions 258) when the heatshield 250 and cut-out regions 258 are viewed from above (i.e., viewed along the angle of view of FIG. 3B). Thus, by providing the cut-out regions 258, large surface mount circuit elements 242 may be mounted within the footprint of the heatsink 250. The cut-out regions 258 may reduce the heat dissipation capabilities of the heatsink by some amount, but the heatsink 250 may still provide sufficient heat dissipation.

As described above, and as can be seen from FIG. 3C, RF transistor amplifier circuit 200 includes a circuit board 210 and an RF transistor amplifier die 230-1 that is flip-chip mounted on an upper surface of the circuit board 210. At least a gate terminal 232 and a drain terminal 234 of the die 230-1 may face an upper surface 212 of the circuit board 210 (in the depicted embodiment, the source terminal 236 also faces the printed circuit board 210). The RF transistor amplifier circuit 200 further includes the heatsink 250 that is mounted on an upper surface of the RF transistor amplifier die 230-1, the heatsink 250 including at least one cut-out region 258. A surface mount circuit element 242 is mounted on the upper surface 212 of the circuit board 210 and extends into the cut-out region 258 in the heatsink 250.

As shown in FIG. 3C, the heatsink 250 may contact the upper surface of the RF transistor amplifier die 230, either directly or through a conductive bonding material. This facilitates venting heat generated in the RF transistor amplifier die 230 from the RF transistor amplifier circuit 200. In addition, the heatsink 250 may also contact the upper surface of one or more of the surface mount circuit elements 240. Even though the surface mount circuit elements 240 are typically passive components, in some cases heat may be generated in these devices (e.g., within resistors or inductors) and hence having the heatsink 250 contact the upper surface of one or more of the surface mount circuit elements 240 may also improve device performance. The heatsink 250 may contact the upper surfaces of these surface mount circuit elements 240, either directly or through a conductive bonding material.

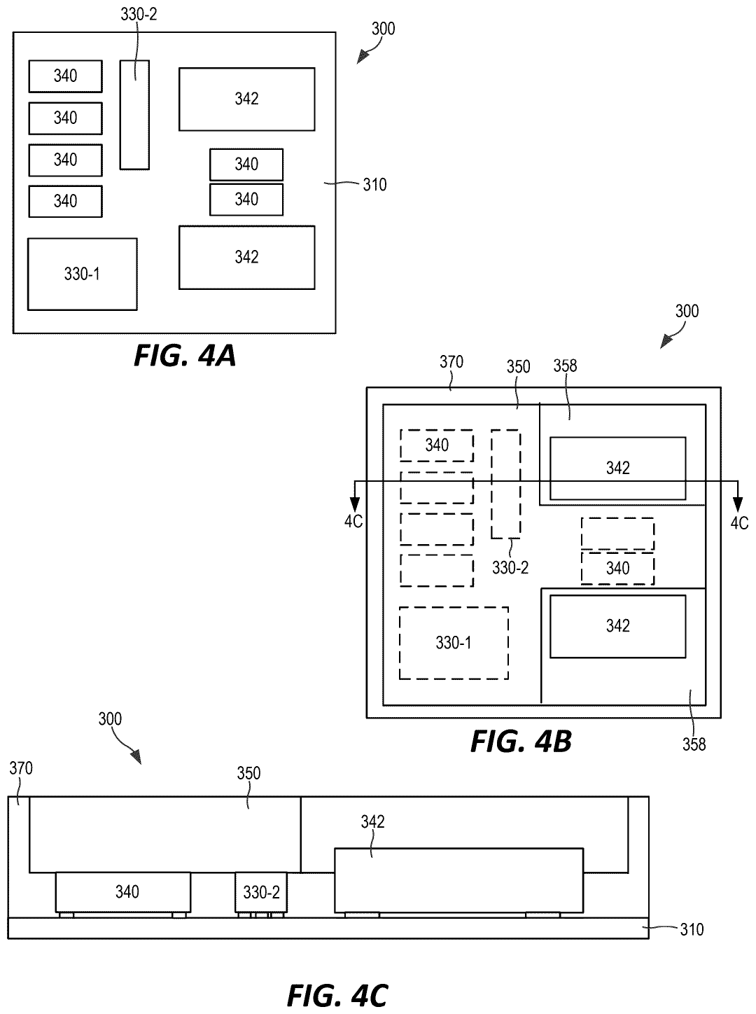

FIG. 4A is a schematic plan view of the printed circuit board and circuit elements of an RF transistor amplifier circuit 300 according to further embodiments of the present invention. In FIG. 4A, the heatsink and molding of the RF transistor amplifier circuit 300 are omitted to show the underlying elements. FIG. 4B is a schematic plan view of the RF transistor amplifier circuit 300 of FIG. 4A once a heatsink of the RF transistor amplifier circuit 300 has been soldered onto the printed circuit board. FIG. 4C is a schematic cross-sectional view of the RF transistor amplifier circuit 300 of FIG. 4B taken along line 4C-4C of FIG. 4B.

RF transistor amplifier circuit 300 is very similar to RF transistor amplifier circuit 200 of FIGS. 3A-3C, with the only difference being that the heatshield 350 of RF transistor amplifier circuit 300 includes “open” cut-out regions 358 as opposed to the closed cut-out regions 258 formed in heatshield 250 of RF transistor amplifier circuit 200. Herein, an “open” cut-out region refers to a cut-out region in a heatshield where the heatshield extends along at least two sides of the cut-out, but does not fully surround the cut-out region when the cut-out region is viewed from above along an axis perpendicular to the major surfaces of the printed circuit board. The cut-out regions 358, when viewed from above, are larger than the large surface mount circuit elements 342. This allows the large surface mount circuit elements 342 to extend into the open cut-outs 358 in the heatsink 350, as shown in FIGS. 4B and 4C. As all other aspects of RF transistor amplifier circuit 300 have been described above in the descriptions of RF transistor amplifier circuits 100 and 200, further description of RF transistor amplifier circuit 300 will be omitted.

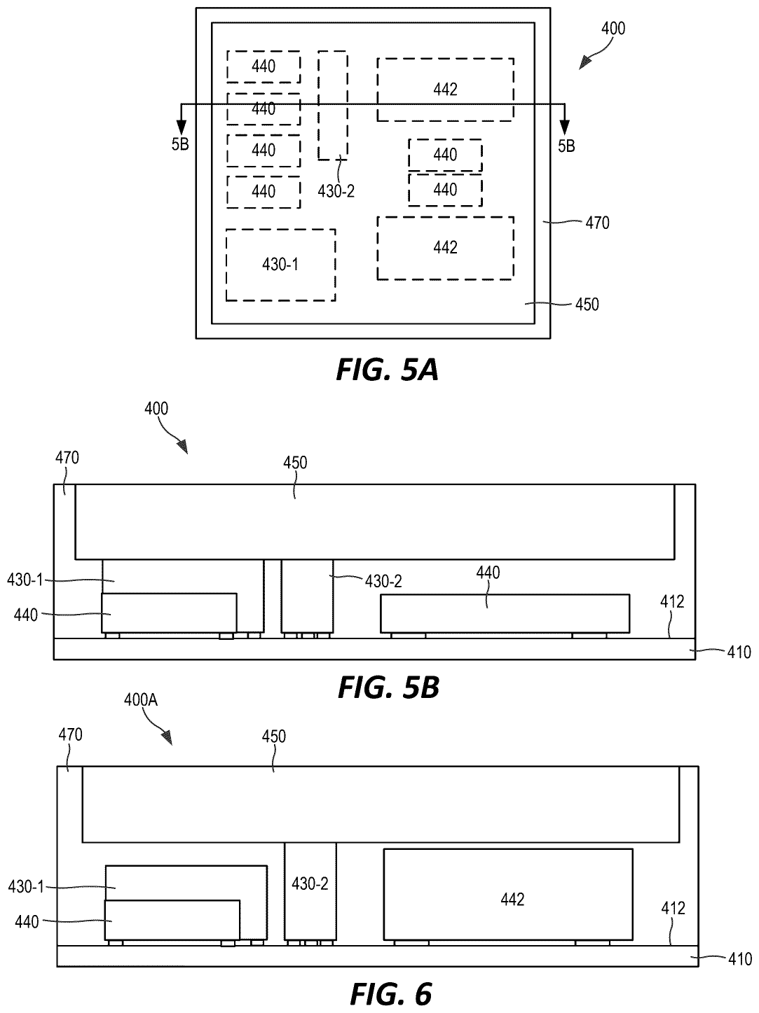

FIG. 5A is a schematic plan view of an RF transistor amplifier circuit 400 according to additional embodiments of the present invention. In FIG. 5A, only a heatshield 450 and a molding 470 of the RF transistor amplifier circuit 400 can be seen in the plan view, so dashed lines are used to show the locations of a printed circuit board 410, RF transistor amplifier dies 430 and surface mount circuit elements 440, 442 that are hidden by the heatshield 450 and the molding 460. FIG. 5B is a schematic cross-sectional view of the RF transistor amplifier circuit 400 of FIG. 5A taken along line 5B-5B of FIG. 5A that shows some of the elements that are hidden from view in FIG. 5A. RF transistor amplifier circuit 400 differs from previously described RF transistor amplifier circuit 100, 200, 300 in that includes thicker RF transistor amplifier dies, and only includes smaller surface mount circuit elements 440.

As shown in FIG. 5B, the first and second RF transistor amplifier dies 430-1, 430-2 are taller (i.e., extend further above the upper surface 412 of printed circuit board 410) than the surface mount circuit elements 440. By using RF transistor amplifier dies 430-1, 430-2 that are taller than the surface mount circuit elements 440, it is possible to mount smaller surface mount circuit elements 440 on the printed circuit board 410 underneath (i.e., vertically overlapping) the heatsink 450 while also soldering the heatsink 450 to the lower surfaces of the flip-chip mounted RF transistor amplifier dies 430-1, 430-2. Thus, the design of FIGS. 5A-5B allows the use of a large heatsink 450 that can provide high levels of heat dissipation while also allowing for the use of a relatively small printed circuit board 410, which can reduce the overall size of the RF transistor amplifier circuit 400.

Typically Group III nitride based RF transistor amplifier die are formed to be relatively thin, having a thickness on the order of 75-100 microns. These Group III nitride based RF transistor amplifier die are grown on a relatively thick silicon carbide growth substrate, and after growth is completed, the substrate is subjected to a grinding or other thinning process that reduces the thickness of the silicon carbide substrate. Typically, the gate and drain terminals of a HEMT Group III nitride based RF transistor amplifier die are formed on the front side of the die, and the source terminal of the HEMT Group III nitride based RF transistor amplifier die is formed on the back side of the die. A plurality of source vias are formed (e.g., by etching) that extend through the silicon carbide substrate to expose the source metallization on the upper surface of the die. A metal layer is deposited on the back side of the die and within the source vias. This metal layer (including the metallization that lines or fills the source vias) acts to electrically connect the source metallization in the active region of the device to the metallization on the back side surface of the device. The metallization on the back side of the device may act as the source terminal for the RF transistor amplifier die.

One issue in forming the source vias is that the etching step used to form the vias will not be a fully isotropic etch. As a result, the cross-sectional area of the via (i.e., the area in planes that are parallel to the major surfaces of the die) become progressively larger with increasing distance from the front side of the die. Each via should have a certain cross-sectional area at the location where the vias contacts the source metallization that is on the front side of the die to make sure that the via makes a good electrical contact. The thicker the die, the larger the opposed bottom end of each source via will be. As a result, if a thick die is used, to keep the source vias from overlapping on the back side of the die, it may be necessary to increase the spacing (pitch) between the source fingers (see discussion of FIGS. 13A-13B below) more than is otherwise necessary. Increasing the pitch between the source fingers is undesirable, as the RF transistor amplifier die is typically the most expensive element of an RF transistor amplifier circuit, and if the pitch is increased, fewer RF transistor die may be formed on a semiconductor wafer. By thinning the silicon carbide substrate before the source vias are formed, any need to increase the pitch of the source fingers (and hence the pitch of the unit cell transistors) may be reduced or eliminated.

As discussed above, the RF transistor amplifier die used in the RF transistor amplifier circuits according to embodiments of the present invention may be flip-chip mounted on printed circuit boards. As a result, the source terminal is formed on the front side of the die rather than on the back side of the die. When the source terminal is formed on the front side of the die, the above described source vias may be omitted. As such, the silicon carbide substrate may be left thicker (e.g., ground away less) without creating other issues.

In some embodiments, the RF transistor amplifier die 430 may each have a thickness of between 125 and 750 microns. Herein, the thickness of an RF transistor amplifier die refers to the thickness of all the layer (not just the semiconductor layers), including the metal layers that form, for example, the gate, drain and source terminals of the device and the metal layers/structures that form the solderable gate, drain and source interconnects. In other embodiments, the thickness may be between 150 and 600 microns, between 175 and 500 microns, or between 225 and 400 microns.

Surface mount capacitors, inductors and resistors are commercially available at low cost, and tend to be sold in standard package sizes. One standard package size is the 0201 package size. By increasing the thickness or “height” of the RF transistor amplifier die to be about 350 microns each, 0201 surface mount circuit elements may readily be mounted on printed circuit board 410 and will fit underneath the heatsink 450 when the heatsink 450 is soldered to the lower surfaces of the RF transistor amplifier die 430-1, 430-2, as shown in FIG. 5A

Other commercially available surface mount circuit elements come in taller packages, such as the 0402 package. The 0402 package height exceeds 350 microns, and hence 0402 surface mount circuit elements will not fit in between the printed circuit board 410 and the heatsink 450 shown in FIG. 5B. However, pursuant to further embodiments of the present invention, the thickness of the RF transistor amplifier die may be increased further in order to allow 0402 surface mount circuit elements 442 to fit in between the printed circuit board 410 and the heatsink 450. This is shown in FIG. 6, which is a schematic cross-sectional view of a modified version 400A of the RF transistor amplifier circuit 400 of FIGS. 5A-5B. As shown in FIG. 6, the height of the RF transistor amplifier die 430-2 is increased to 500 microns or more, which allows room for 0402 surface mount circuit elements 442 to fit in between the printed circuit board 410 and the heatsink 450. In some example embodiments, the height of each RF transistor amplifier die 430 may be between 250 and 750 microns, between 300 and 600 microns, or between 350 and 500 microns.

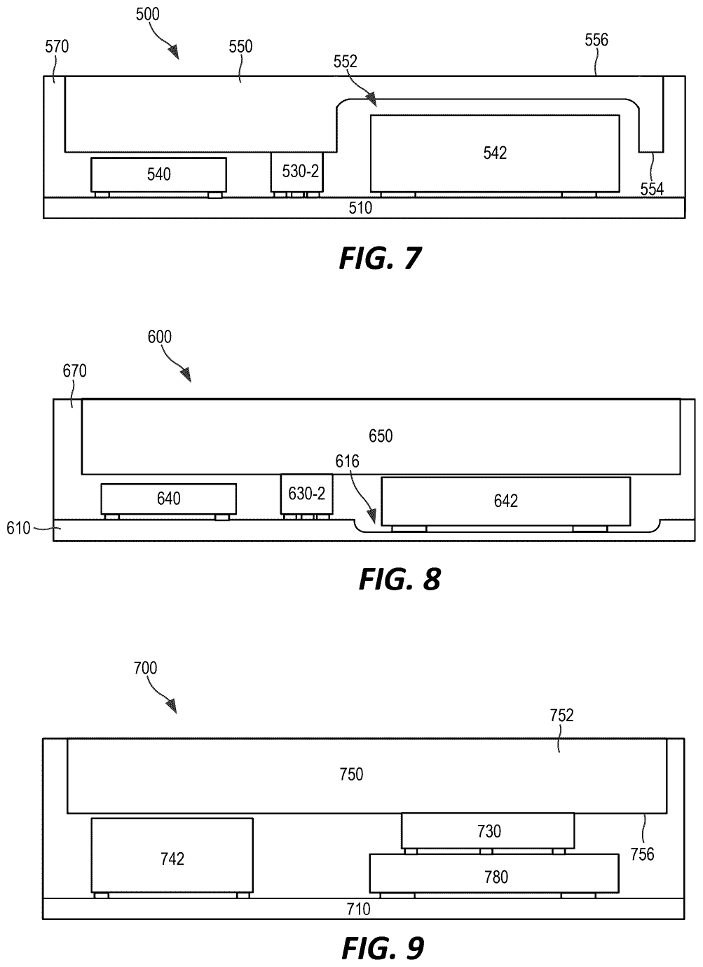

FIG. 7 is a schematic cross-sectional view of an RF transistor amplifier circuit 500 according to still further embodiments of the present invention that includes a heatsink 550 having a recessed lower surface. A plan view of RF transistor amplifier circuit 500 may be identical to the plan view of RF transistor amplifier circuit 400 shown in FIG. 5A, so a plan view of RF transistor amplifier circuit 500 is not provided separately.

As shown in FIG. 7, RF transistor amplifier circuit 500 differs from RF transistor amplifier circuit 400 in that RF transistor amplifier circuit 500 (1) includes standard height (e.g., 75-100 microns) RF transistor amplifier die 530-1, 530-2 and (2) the heatsink 550 of RF transistor amplifier circuit 500 includes one or more recesses 552 on a lower surface 554 thereof. The recesses 552 provide headroom so that larger height surface mount circuit elements 542 (e.g., surface mount circuit elements in 0402 packages) can be mounted on the printed circuit board 510 while still fitting in between the printed circuit board 510 and the heatsink 550. The recesses 552 may be formed above the locations where the larger surface mount circuit elements 542 are to be positioned on the printed circuit board 510, and the footprint of each recess 552 may be larger than the footprint of the corresponding surface mount circuit elements 542 so that each larger surface mount circuit element 542 may fit within the recess 552. The recesses 552 may be formed, for example, by masking the lower surface 554 of the heatsink 550 and performing a chemical etch thereon or by a machining or grinding operation.

RF transistor amplifier circuit 500 advantageously provides a heatsink 550 having a continuous upper surface 556, typically in a polygon (e.g., rectangular) shape, which meets customer expectations. This continuous upper surface 556 may also cooperate well with any additional active heat removal equipment that the customer may ultimately use to further vent heat from the RF transistor amplifier circuit 500. The recesses 552 in the heatsink 550 will likely cause a small decrease in the thermal transfer characteristics of the heatsink 550 as compared to the heatsink 450 of FIGS. 5A-5B, but this can be compensated for by, for example, slightly increasing the footprint of the heatsink 550.

FIG. 8 is a schematic cross-sectional view of an RF transistor amplifier circuit 600 according to yet additional embodiments of the present invention. RF transistor amplifier circuit 600 differs from the previous embodiments in that it use a printed circuit board 610 having a recessed upper surface to create additional headroom so that surface mount circuit elements 642 can be positioned in between the printed circuit board 610 and the heatsink 660.

As shown in FIG. 8, printed circuit board 610 includes one or more recesses 616 where the upper surface 612 of the dielectric substrate of printed circuit board 610 is omitted or removed. The printed circuit board 610 may include at least three metallization layers (not shown), namely a top metallization layer, a bottom metallization layer and an intermediate metallization layer. The RF transistor amplifier die 630 and the smaller surface mount circuit elements 640 may be mounted on metal pads provided in the top metallization layer. The larger surface mount circuit elements 642 may be mounted on metal pads provided in the intermediate metallization layer.

FIG. 9 is a schematic cross-sectional view of an RF transistor amplifier circuit 700 according to further embodiments of the present invention. As shown in FIG. 9, RF transistor amplifier circuit 700 includes a printed circuit board 710 that has an integrated passive device (“IPD”) 780 mounted thereon. An IPD refers to a circuit element that includes passive electronic elements such as capacitors, inductors, resistors and the like. IPDs may be formed using standard wafer fabrication technologies such as thin film and photolithography processing. IPDs can be designed as flip chip mountable components. The substrates for the IPDs usually are thin film substrates such as silicon, alumina, or glass, which may allow for ease in manufacturing and packaging with active transistor dies. As shown, the IPD 780 may be flip chip mounted on the printed circuit board 710, and an RF transistor amplifier die 730 may be flip-chip mounted on the IPD 780. By mounting the RF transistor amplifier die 730 on the IPD 780, a combined structure 780/730 is formed, which effectively increases the height of the RF transistor amplifier die 730. As such, a heatsink 750 may be mounted on the printed circuit board 710 so that a lower surface 756 of a plate-like region 752 of the heatsink 750 can be directly bonded to the back side of the RF transistor amplifier die 730 (e.g., through a conductive bonding material), and the heatsink 750 may be mounted sufficiently above the printed circuit board 710 to make room to mount even large surface mount circuit elements 742 on the printed circuit board 710 underneath the heatsink 750. It will be appreciated that the positions of the RF transistor amplifier die 730 and the IPD 780 could be reversed so that the RF transistor amplifier die 730 is mounted on the printed circuit board 710 and the IPD 780 is mounted on the RF transistor amplifier die 730 to be in between the RF transistor amplifier die 730 and the heatsink 750. However, the arrangement shown in FIG. 9 may be preferred in many applications as it allows the heatsink 750 to directly contact the RF transistor amplifier die 730 for efficient venting of heat from the RF transistor amplifier die 730.

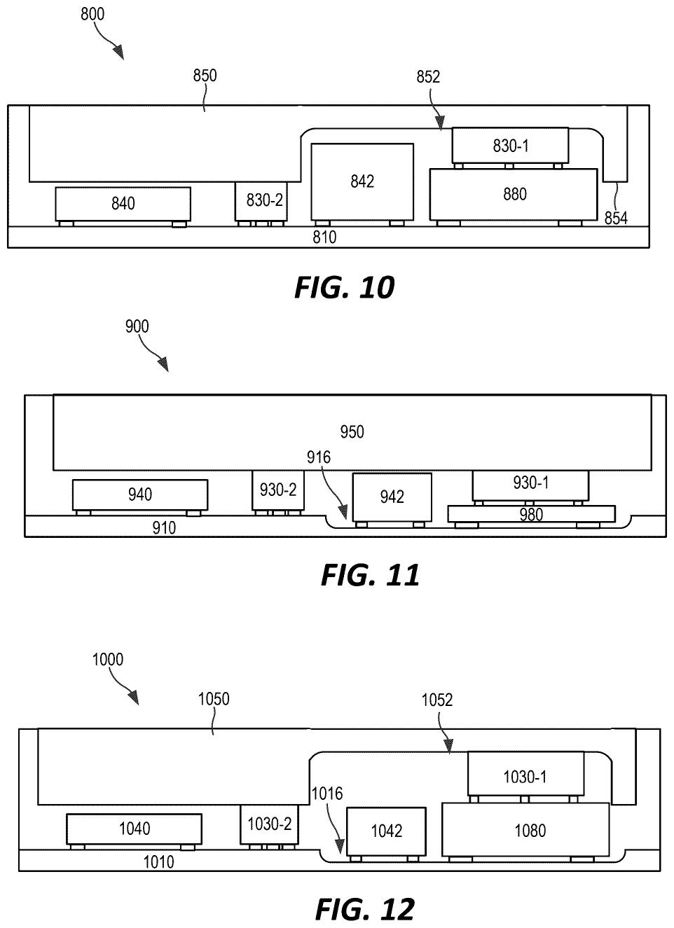

FIG. 10 is a schematic cross-sectional view of an RF transistor amplifier circuit 800 according to still further embodiments of the present invention. As shown in FIG. 10, RF transistor amplifier circuit 800 includes a printed circuit board 810 that has an IPD 880, a small surface mount circuit element 840, a large surface mount circuit element 842 and a second RF transistor amplifier die 830-2 mounted thereon. The IPD 880 and the RF transistor amplifier die 830-2 are each flip-chip mounted on the printed circuit board 810. In addition, as in the embodiment of FIG. 9, a first RF transistor amplifier die 830-1 is flip-chip mounted on the IPD 880. As in the embodiment of FIG. 7, the heatsink 850 includes a recess 852 in a lower surface of a plate-like region of the heatsink 850. The large surface mount circuit element 842 and the first RF transistor amplifier die 830-1 each extend upwardly into the recess 852. By providing the recess 852, both RF transistor amplifier dies 830-1, 830-2 may directly contact the heatsink 850. Moreover, the recess 852 also provides head room for mounting the large surface mount circuit element 842 in between the printed circuit board 810 and the heatsink 850.

FIG. 11 is a schematic cross-sectional view of an RF transistor amplifier circuit 900 according to still further embodiments of the present invention. As shown in FIG. 11, RF transistor amplifier circuit 900 includes a printed circuit board 910 that has an IPD 980, a small surface mount circuit element 940, a large surface mount circuit element 942 and a second RF transistor amplifier die 930-2 mounted thereon. The IPD 980 and the RF transistor amplifier die 930-2 are each flip-chip mounted on the printed circuit board 910. In addition, as in the embodiments of FIGS. 9-10, a first RF transistor amplifier die 930-1 is flip-chip mounted on the IPD 980. As in the embodiment of FIG. 8, the printed circuit board 910 includes a recess 916 in an upper surface thereof. The large surface mount circuit element 942 and the IPD 980 are each mounted in the recessed region 916 of the printed circuit board 910. By providing the recess 916, it is possible to have a plate-like region of a heatsink 950 be bonded to both the first and second RF transistor amplifier dies 930-1, 930-2, even though only one of these die is mounted on an IPD. The recessed region 916 in printed circuit board 910 also allows mounting large surface mount circuit elements 942 on the printed circuit board 910 (namely within the recessed region 916 thereof) and still have sufficient head room such that large surface mount circuit elements 942 may fit in between the printed circuit board 910 and the heatsink 950 while still allowing the heatsink to contact the RF transistor amplifier die 930-1, 930-2.

FIG. 12 is a schematic cross-sectional view of an RF transistor amplifier circuit 1000 according to further embodiments of the present invention that combines the techniques shown in FIGS. 10 and 11. In particular, as shown in FIG. 12, RF transistor amplifier circuit 1000 includes a printed circuit board 1010 that has an IPD 1080, a small surface mount circuit element 1040, a large surface mount circuit element 1042 and a second RF transistor amplifier die 1030-2 mounted thereon. A first RF transistor amplifier die 1030-1 is also provided that is flip-chip mounted on the IPD 1080. The heatsink 1050 includes a recess 1052 in its lower surface, and the printed circuit board 1010 includes a recess 1016 in an upper surface thereof. The large surface mount circuit element 1042 and the IPD 1080 are each mounted in the recessed region 1016 of the printed circuit board 1010. The large surface mount circuit element 1042 and the first RF transistor amplifier die 1030-1 each extend upwardly into the recess 1052 in the heatsink 1050. This arrangement allows both RF transistor amplifier dies 1030-1, 1030-2 to directly contact the heatsink 1050 (e.g., through a conductive bonding material), and further provides head room for mounting the large surface mount circuit element 1042 in between the printed circuit board 1010 and the heatsink 1050.

Each RF transistor amplifier circuit described above is illustrated as including two RF transistor amplifier die. The two RF transistor amplifier die may, for example, be electrically connected in series (e.g., so that the RF transistor amplifier circuit includes a pre-amplifier and a main amplifier) or may be electrically connected in parallel (e.g., in a Doherty amplifier configuration). It will be appreciated that the RF transistor amplifier circuits according to embodiments of the present invention may include other numbers of RF transistor amplifier die, such as a single RF transistor amplifier die or three, four or more RF transistor amplifier die that are electrically connected in series and/or in parallel. Each RF transistor amplifier die may include an input impedance matching circuit and/or an input harmonic termination circuit, and/or may include an output impedance matching circuit and/or an output harmonic termination circuit. When two RF transistor amplifier die are connected in series, an interstage impedance matching circuit and/or an interstage harmonic termination circuit may be provided along the electrical connection between the two RF transistor amplifier die.

While the RF transistor amplifier circuits according to embodiments of the present invention illustrated above each use a conventional printed circuit board, it will be appreciated that other types of circuit boards may be used such as, for example, a redistribution layer (“RDL”) laminate structure. An RDL laminate structure refers to a substrate that has conductive layer patterns and/or conductive vias for electrical and/or thermal interconnection. RDL laminate structures may be fabricated using semiconductor processing techniques by depositing conductive and insulating layers and/or patterns on a base material and by forming vias and copper routing patterns within the structure for transmitting signals through the RDL laminate structure. Other circuit boards that could be used in place of the printed circuit boards discussed above include specialized printed circuit board (e.g., a metal core printed circuit board) or a ceramic substrate that includes conductive vias and/or pads.

As discussed above, the RF transistor amplifier circuits according to embodiments of the present invention may include one or more Group III nitride based RF transistor amplifiers. FIGS. 13A and 13B schematically illustrate a Group III nitride-based RF transistor amplifier die 1100 that may be used as the RF transistor amplifier die in any of the RF transistor amplifier circuits according to embodiments of the present invention. In particular, FIG. 13A is a schematic plan view of the RF transistor amplifier die 1100. In FIG. 13A, most of the metallization that is on the front side of the semiconductor layer structure has been removed to illustrate the metallization that directly contacts the semiconductor layer structure of RF transistor amplifier die 1100. FIG. 13B is a schematic cross-sectional view of the RF transistor amplifier die 1100 taken along line 13B-13B of FIG. 13A. It will be appreciated that FIGS. 13A and 13B are highly simplified diagrams, and that actual RF transistor amplifier die may include many more unit cells and various circuitry and elements that are not shown in the simplified figures herein.

As shown in FIG. 13A, the RF transistor amplifier die 1100 includes a front side metallization structure 1110 that is formed on a semiconductor layer structure 1150. The front side metallization structure 1110 includes a gate bus 1112 and a drain bus 1114, a plurality of gate fingers 1122, a plurality of drain fingers 1124 and a plurality of source fingers 1126, all of which are formed on a front side of the semiconductor layer structure 1150. The gate fingers 1122, drain fingers 1124 and source fingers 1126 may extend in parallel to each other, with the gate fingers 1122 extending from the gate bus 1112 in a first direction and the drain fingers 1124 extending from the drain bus 1114 in a direction opposite the first direction. Each gate finger 1122 may be positioned between a drain finger 1114 and a source finger 1126.

The gate bus 1112 and the gate fingers 1122 may be implemented as a first monolithic metal pattern. The gate fingers 1122 may be formed of materials that are capable of making a Schottky contact to a Group III nitride-based semiconductor material, such as Ni, Pt, Cu, Pd, Cr, W and/or WSiN. The gate bus 1112 and the gate fingers 1122 are part of a gate electrode structure of the RF transistor amplifier die 1100. The upper portion (not shown) of the gate electrode may act as the gate terminal of the RF transistor amplifier die 1100.

The drain bus 1114 and the drain fingers 1124 may be implemented as a second monolithic metal pattern. The drain fingers 1124 may include a metal, such as TiAlN, that can form an ohmic contact to Group III nitride-based materials. The drain bus 1114 and the drain fingers 1124 are part of a drain electrode of the RF transistor amplifier die 1100. The upper portion (not shown) of the drain electrode may act as a drain terminal of the RF transistor amplifier die 1100.

The source fingers 1126 may include a metal, such as TiAlN, that can form an ohmic contact to Group III nitride-based materials. The source fingers 1126 are physically and electrically connected to a source bus (not shown) that is connected to a source terminal of the RF transistor amplifier die 1100. As discussed above, the source terminal is also located on the top side of the semiconductor layer structure 1150.

One or more interlayer insulating layers 1118 (see FIG. 13B) are formed that isolate the gate metallization 1112, 1122, the drain metallization 1114, 1124 and the source metallization 1126 from each other. The interlayer insulating layer(s) 1118 may include a dielectric material, such as SiN, SiO₂, etc.

The RF transistor amplifier die 1100 includes a plurality of unit cell transistors 1102, one of which is indicated in the dashed box in FIG. 13A. The unit cell transistor 1102 includes a gate finger 1122, a portion of a drain finger 1124 and a portion of a source finger 1126 along with the portions of the semiconductor layer structure 1150 underlying the identified gate finger 1122, drain finger 1124 and source finger 1126. Since all of the gate fingers 1122 are electrically connected to a common gate bus 1112, all of the drain fingers 1124 are electrically connected to a common drain bus 1114, and all of the source fingers 1126 are electrically connected to a common source bus (not shown), it can be seen that the unit cell transistors 1102 are all electrically connected together in parallel. The RF transistor amplifier die 1100 may comprise a Group III nitride-based HEMT RF transistor amplifier.

FIG. 13B illustrates the semiconductor layer structure 1150 in more detail. As shown in FIG. 13B, the semiconductor layer structure 1150 includes a plurality of semiconductor layers. In the depicted embodiment, a total of two semiconductor layers are shown, namely a channel layer 1154 and a barrier layer 1156 that is on a top side of the channel layer 1154. The semiconductor layer structure 1150 may (and typically will) include additional semiconductor and/or non-semiconductor layers. For example, the semiconductor layer structure 1150 may include a growth substrate 1152 on which the other semiconductor layers are grown. The growth substrate 1152 may comprise, for example, a 4H—SiC or 6H—SiC substrate. In other embodiments, the growth substrate 1152 may be comprise a different semiconductor material (e.g., silicon or a Group III nitride-based material, GaAs, ZnO, InP) or a non-semiconductor material (e.g., sapphire).

Optional buffer, nucleation and/or transition layers (not shown) may be provided on the growth substrate 1152 beneath the channel layer 1154. For example, an AlN buffer layer may be included to provide an appropriate crystal structure transition between a SiC growth substrate 1152 and the remainder of the semiconductor layer structure 1150. Additionally, strain balancing transition layer(s) may also be provided.

In some embodiments, the channel layer 1154 is a Group III nitride material, such as AlₓGa₁₋ₓN where 0≤x<1, provided that the energy of the conduction band edge of the channel layer 1154 is less than the energy of the conduction band edge of the barrier layer 1156 at the interface between the channel and barrier layers 1154, 1156. In certain embodiments, x=0, indicating that the channel layer 1154 is gallium nitride (“GaN”). The channel layer 1154 may also be other Group III nitrides such as InGaN, AlInGaN or the like. The channel layer 1154 may be undoped or unintentionally doped and may be grown to a thickness of, for example, greater than about 20 521 The channel layer 1154 may also be a multi-layer structure, such as a superlattice or combinations of GaN, AlGaN or the like.

The channel layer 1154 may have a bandgap that is less than the bandgap of at least a portion of the barrier layer 1156, and the channel layer 1154 may also have a larger electron affinity than the barrier layer 1156. In certain embodiments, the barrier layer 1156 is AlN AlInN, AlGaN or AlInGaN with a thickness of between about 0.1 nm and about 10 nm or more. In particular embodiments, the barrier layer 1156 is thick enough and has a high enough Al composition and doping to induce a significant carrier concentration at the interface between the channel layer 1154 and the barrier layer 1156.

The barrier layer 1156 may be a Group III nitride and may have a bandgap larger than that of the channel layer 1154 and a smaller electron affinity than the channel layer 1154. The barrier layer 1156 may include AlGaN, AlInGaN and/or AlN or combinations of layers thereof. In certain embodiments, the barrier layer 1156 is undoped or doped with an n-type dopant to a concentration less than about 10¹⁹ cm⁻³. In some embodiments, the barrier layer 1156 is AlₓGa₁₋ₓN where 0<x<1.

Due to the difference in bandgap between the barrier layer 1156 and the channel layer 1154 and piezoelectric effects at the interface between the barrier layer 1156 and the channel layer 1154, a two dimensional electron gas (2DEG) is induced in the channel layer 1154 at a junction between the channel layer 1154 and the barrier layer 1156. The 2DEG acts as a highly conductive layer that allows conduction between the source region of each unit cell transistor 1102 and its associated drain region, where the source region is the portion of the semiconductor layer structure 1150 that is directly underneath the source finger 1126 and the drain region is the portion of the semiconductor layer structure 1150 that is directly underneath the corresponding drain finger 1124.

The packaged RF transistor amplifier circuits according to embodiments of the present invention may also be implemented using discrete elements such as individual RF transistor amplifier die and additional, separate elements such as matching circuits, or may be implemented on a single semiconductor die as a monolithic microwave integrated circuits (MIMIC). A MIMIC refers to an integrated circuit that operates on radio and/or microwave frequency signals in which all of the circuitry for a particular function is integrated into a single semiconductor chip. MIMIC RF transistor amplifiers typically include a plurality of unit cell HEMT transistors that are connected in series and/or parallel, along with associated matching circuits and feed networks.

The RF transistor amplifier circuits according to embodiments of the present invention may be designed to operate in a wide variety of different frequency bands. In some embodiments, the RF transistor amplifiers may be configured to operate at frequencies greater than 1 GHz. In other embodiments, these RF transistor amplifier dies may be configured to operate at frequencies greater than 2.5 GHz. In still other embodiments, the RF transistor amplifier dies may be configured to operate at frequencies greater than 3.1 GHz. In yet additional embodiments, these RF transistor amplifier dies may be configured to operate at frequencies greater than 5 GHz. In some embodiments, these RF transistor amplifier dies may be configured to operate in at least one of the 2.5-2.7 GHz, 3.4-4.2 GHz, 5.1-5.8 GHz, 12-18 GHz, 18-27 GHz, 27-40 GHz or 40-75 GHz frequency bands or sub-portions thereof.

Although embodiments of the present invention have been discussed above with respect to a RF transistor amplifier dies that are implemented using HEMT devices, it will be understood that other types of semiconductor devices may be formed in the semiconductor layer structure without deviating from the present invention. For example, the semiconductor layer structure may include a MOSFET, a DMOS transistor, and/or a MESFET in other embodiments.

Embodiments of the present inventive concepts have been described above with reference to the accompanying drawings, in which embodiments of the invention are shown. This inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. Like numbers refer to like elements throughout.

In the specification and the figures, two-part reference numbers (i.e., two numbers separated by a dash) may be used to identify like elements. When such two-part reference numbers are employed, the full reference numeral may be used to refer to a specific instance of the element, while the first part of the reference numeral may be used to refer to the elements collectively.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the terms “comprises” “comprising,” “includes” and/or “including” specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

In the drawings and specification, there have been disclosed typical embodiments of the invention and, although specific terms are employed, they are used in a generic and descriptive sense only and not for purposes of limitation, the scope of the invention being set forth in the following claims.

1. A transistor package, comprising:
a circuit board;
a transistor die that has a gate terminal, a drain terminal and a source terminal, the transistor die flip-chip mounted so that the gate terminal and the drain terminal face the upper surface of the circuit board;
a heatsink mounted on an upper surface of the transistor die; and
a plurality of surface mount circuit elements mounted on the upper surface of the circuit board so that a footprint of the heatsink vertically overlaps at least one of the plurality of surface mount circuit elements.

2. The transistor package of claim 1, wherein a height of the transistor die is at least 300 microns.

3. The transistor package of claim 1, wherein the heatsink includes a first cut-out region, and a first of the plurality of surface mount circuit elements extends into the cut-out region in the heatsink.

4-6. (canceled)

7. The transistor package of claim 1, further comprising a molding material that at least partially fills a space between the circuit board and the heatsink.

8. The transistor package of claim 1, wherein the heatsink is directly connected to the transistor die through a thermally conductive bonding material.

9. The transistor package of claim 1, wherein the heatsink contacts at least one of the plurality of surface mount circuit elements either directly or through a thermally conductive bonding material.

10. (canceled)

11. The transistor package of claim 1, wherein the heatsink includes a plate-like portion that extends in parallel to the circuit board.

12. The transistor package of claim 11, wherein the heatsink further includes a plurality of legs that extend downwardly from the plate-like portion, wherein at least some of the legs are soldered to the circuit board.

13. The transistor package of claim 11, wherein a lower surface of the plate-like portion includes a recess, and a first of the plurality of surface mount circuit elements extends upwardly from the circuit board into the recess.

14. The transistor package of claim 1, wherein an upper surface of the circuit board includes a recessed region, and a first of the plurality of surface mount circuit elements extends into the recessed region.

15-24. (canceled)

25. The transistor package of claim 1, further comprising an integrated passive device that is mounted on the circuit board, wherein the transistor die is flip-chip mounted on the integrated passive device.

26. A transistor package, comprising:
a circuit board;
a transistor die that has a gate terminal, a drain terminal and a source terminal, the transistor die flip-chip mounted so that the gate terminal and the drain terminal face the upper surface of the circuit board;
a heatsink mounted on an upper surface of the transistor die, the heatsink including at least one cut-out region; and
a first surface mount circuit element mounted on the upper surface of the circuit board, the first surface mount circuit element extending into the cut-out region in the heatsink.

27. The transistor package of claim 26, wherein the cut-out region is a closed cut-out region.

28-30. (canceled)

31. The transistor package of claim 26, wherein a first height of the first surface mount circuit element is greater than or equal to a second height of the transistor die.

32. (canceled)

33. The transistor package of claim 26, wherein the heatsink includes a plate-like portion, and a plurality of legs that extend downwardly from the plate-like portion, wherein at least some of the legs are soldered to the circuit board.

34-38. (canceled)

39. A transistor package, comprising:
a circuit board;
a transistor die mounted directly or indirectly on an upper surface of the circuit board;
a heatsink mounted on the transistor die opposite the circuit board, the heatsink including a plate-like portion that extends parallel to the circuit board, where a lower surface of the plate-like portion includes a recess; and
a surface mount circuit element mounted on an upper surface of the circuit board and extending into the recess.

40. (canceled)

41. The transistor package of claim 39, further comprising a molding material that at least partially fills a space between the circuit board and the heatsink.

42. The transistor package of claim 39, wherein the heatsink is directly connected to the transistor die through a thermally conductive bonding material.

43. The transistor package of claim 42, further comprising a plurality of additional surface mount circuit elements mounted on the upper surface of the circuit board, wherein the heatsink contacts at least one of the plurality of additional surface mount circuit elements either directly or through a thermally conductive bonding material.

44. The transistor package of claim 39, wherein the transistor die is a radio frequency (“RF”) transistor amplifier die that includes a gate terminal, a drain terminal and a source terminal, and the RF transistor amplifier die is flip-chip mounted on an upper surface of the circuit board so that at least the gate terminal and the drain terminal face the upper surface of the circuit board.

45-46. (canceled)

47. The transistor package of claim 39, wherein the heatsink includes a plate-like portion, and a plurality of legs that extend downwardly from the plate-like portion, wherein at least some of the legs are soldered to the circuit board.

48-70. (canceled)
